(19) United States
(12) Patent Application Publication
(10) Pub. No.: US 2003/0034541 A1
(43) Pub. Date: Feb. 20, 2003

(54) Structure and method for fabricating fault tolerant semiconductor structures with fault remediation utilizing the formation of a compliant substrate

(75) Inventors: Raymond B. Essick, Glen Ellyn, IL (US); Mihir A. Pandya, Austin, TX (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/930,270

(22) Filed: Aug. 16, 2001

(51) Int. Cl. H01L 29/00; H01L 29/167; H01L 29/207; H01L 29/227; H01L 23/58; H01L 31/0288

(52) U.S. Cl. 257/505; 257/609; 257/631

(57) ABSTRACT

Fault remediation functions are embodied in a semiconductor structure in which high quality epitaxial layers of monocrystalline materials are made to overlie monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. Fault remediation is carried out in one instance by recognizing the presence of a fault and in another instance by providing fault correction. The fault remediation functions may be combined with conventional data-emitting circuitry to form a monolithic structure having a common substrate.

### FIELD OF THE INVENTION

This invention relates generally to semiconductor structures, including fault diagnostics, as well as data recovery with fault remediation, and to a method for their fabrication. More specifically, the present invention relates to semiconductor structures, including their fabrication and use, that includes, at least in part, a monocrystalline material layer comprised of semiconductor material, compound semiconductor material, and/or other types of material such as metals and nonmetals formed by utilizing a compliant substrate and which have one or more fault tolerant features.

### BACKGROUND OF THE INVENTION

A number of applications for semiconductor structures implementing computation logic are directed toward safety critical systems. This means that the systems are expected to continue operating correctly even in the presence of faults. At the very least, there should be graceful degradation or an orderly withdrawal of computational facility in the event of loss of data integrity. Computation systems for many practical applications are expected to be fault-tolerant. Examples of applications where fault tolerance are requisite include, for example, automobile systems, avionics, space applications, factory automation, etc. Fault tolerance is a necessary feature of systems whose failure could result in injury to person or property or substantial monetary costs. In addition to being fault-tolerant, a vast number of such systems, e.g., embedded space applications, are expected to operate in real-time, i.e., perform computations within specified time constraints.

In addition, some critical systems are expected to operate reliably in very hostile environments, such as those encountered in outer space, nuclear reactors, etc., where systems are subjected to prolonged exposure to harmful radiation. In

these types of systems, it is imperative that computation and logic elements, such as memory, continue to operate correctly even in the presence of faults.

The present invention relates generally to systems embodied in semiconductor structures which include, at least in part, a monocrystalline material layer comprised of either, semiconductor material, compound semiconductor material, and/or other types of materials (such as metals and non-metals) formed by utilizing a compliant substrate.

Semiconductor structures often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer, such as a silicon wafer, an integrated device structure could be achieved that took advantage of the best properties of both the silicon and the high quality monocrystalline material.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of yet another embodiment of a device structure in accordance with the invention;

FIGS. 24 and 25 illustrate schematically, in cross-section, device structures that can be used in accordance with various embodiments of the invention;

FIGS. 26-30 illustrate a cross-section of the use of an integrated circuit portion including a compound semiconductor part, a bipolar part, and a MOS part in accordance with what is shown herein;

FIGS. 31-37 are schematic illustrations of fault-remediation systems of a first, fault diagnostic type;

FIG. 38 is a schematic illustration of a fault remediation system of a second, fault recovery type; and

FIG. 39 is a cross-sectional view of a semiconductor structure as can be used in accordance with various embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE PREFERRED EMBODIMENTS

The present invention is directed to semiconductor structures having fault remediation properties so as to render the semiconductor structures “fault-tolerant.” As will be seen herein, the term “fault-tolerant” refers to the remediation of faults encountered in operational systems, especially systems vulnerable to deteriorate operation when placed in environments of elevated radiation levels. The “data systems” contemplated herein include data generating, manipulating, transmitting and storage systems, as well as virtually any structure in which data is involved for internal or external purposes. For example, internal data may be involved solely in the self-containing operation of a given system, without regard to contact with the “outside world.” In one aspect of the present invention, fault remediation is provided for semiconductor structures and systems relating to such structures which must maintain ongoing reliable operation in real-time, even when a resident in high radiation environments. There are a wide variety of data-related circuits and devices designed or adapted for use, including real-time use in high radiation environments, such as those encountered in earth satellites, space vehicles and other equipment employed in outer space as well as terrestrial-based nuclear-powered ships, generators, medical reactors and a wide variety of research devices.

According to one aspect of the present invention, two types of fault remediation are provided. In a first type of fault remediation, the present invention provides fault diagnostics, which are consistently reliable despite exposure to elevated radiation levels. In a second type of fault remediation, fault recovery is implemented which again is rendered consistently reliable despite residence in elevated radiation environments. The present invention takes advantage of compound semiconductors of the type described above, which include a monocrystalline material layer comprised of either semiconductor material, compound semiconductor material and/or other types of material (such as metals and nonmetals) formed by utilizing a compliant substrate. Utilizing one type of semiconductor structure described above, the present invention utilizes GaAs compound semiconductor structure to implement fault remediation functions, which render a wide variety of well-understood data-related systems functionally capable of reliable operation in higher radiation environments. According to certain aspects of the present invention, a GaAs-based fault remediation semiconductor structure is integrated with any of a wide variety of known data-related systems implemented in materials other than GaAs, such as silicon, for example. Preferably, the present invention provides device integration by utilizing a common substrate for both fault remediation and data circuits. For example, a common silicon substrate is employed for conventional data-related functions. The fault remediation functions are provided in radiation-tolerant fast operation GaAs-based circuitry built on the silicon substrate, using novel techniques to be described herein. In other aspects of the present invention, fault remediation provides two general types of responses to the detection of intermittent or random faults. In a first type of response, the remediation circuit provides notification for operational direction to the data circuitry. In a second type of response the remediation circuit takes corrective action, apart from the data circuit. According to another aspect of the present invention, it is preferred that the relatively high speed of GaAs-based remediation devices be beneficially employed to cause an immediate reiteration of the faulty data. Because of the intermittent or random malfunction of the data device, it is expected that reiteration will not result in faulty data. Oftentimes, it is faster to immediately reiterate data, than to return to the data-related functions at a later time, when the data device is processing data irrelevant to the fault. In this manner, the present invention avoids stopping program execution.

1. Semiconductor Structures

Before proceeding with a discussion of the fault remediation provided by the present invention, semiconductor structures preferred for carrying out the present invention will be described. These semiconductor structures are formed, at least in part, using a monocrystalline material layer comprised of semiconductor material, compound semiconductor material, and/or other types of material such as metals and non-metals, formed by utilizing a compliant substrate.

As contemplated herein, the term “semiconductor structure” refers to semiconductor structures, devices, integrated circuits, systems of all types and other useful items of an electronic nature, whether of a mixed mode, mixed logic or other mixed nature, or not. As will be explained in greater detail herein, semiconductor structures according to principles of the present invention take advantage of semiconductor structures having certain features, which will now be generally summarize with reference to two examples. In a general description of a first example, semiconductor structures of interest have features which include a monocrystalline silicon substrate, an amorphous oxide material overlying the monocrystalline silicon substrate, a monocrystalline perovskite oxide material overlying the amorphous oxide material, and a monocrystalline compound semiconductor material overlying the monocrystalline perovskite oxide material. The semiconductor structure features may include a template layer between the monocrystalline perovskite oxide layer and the monocrystalline compound semiconductor material. The semiconductor structure features may also include a buffer material of monocrystalline semiconductor material formed between the monocrystalline perovskite oxide material and the monocrystalline compound semiconductor material, and a template layer may also be formed between the monocrystalline perovskite oxide material and the buffer material.

In a general description of a second example, semiconductor structures of interest have features which include a monocrystalline substrate characterized by a first lattice constant; a monocrystalline insulator layer having a second lattice constant different than the first lattice constant overlying the monocrystalline substrate, an amorphous oxide layer between the monocrystalline substrate and the monocrystalline insulator layer; and a monocrystalline compound semiconductor layer having a third lattice constant different than the first lattice constant overlying the monocrystalline insulator layer; wherein the second lattice constant is selected to be either equal to the third lattice constant; or intermediate the first and third lattice constant. The semiconductor structure features may also include a template layer between the monocrystalline insulator layer and the monocrystalline compound semiconductor layer. Further, optional additional features may include a buffer layer between the monocrystalline insulator layer and the monocrystalline compound semiconductor layer.

For purposes of illustration and not limitation, certain examples of semiconductor structures and devices, and their general method of fabrication, which benefit from the present invention, will now be given. Referring initially to FIG. 1, a schematic illustration of a semiconductor structure 20 is shown in cross section. Semiconductor structure 20 includes a monocrystalline substrate 22, accommodating buffer layer 24 comprising a monocrystalline material, and a monocrystalline material layer 26. In this context, the term “monocrystalline” will have the meaning commonly used within the semiconductor industry. The term will refer to materials that are a single crystal or that are substantially a single crystal and will include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer 24 and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and, by doing so, aids in the growth of a high crystalline quality accommodating buffer layer.

Substrate 22, in accordance with an embodiment of the invention, is a monocrystalline semiconductor or compound semiconductor wafer, preferably of a large diameter. The wafer can be of, for example, a material from Group IV of the periodic table. Examples of Group IV semiconductor materials, include silicon, germanium, mixed silicon and germanium, mixed silicon and carbon, mixed silicon, germanium and carbon, and the like. Preferably, substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides, such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides, such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or nonmetal materials, which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

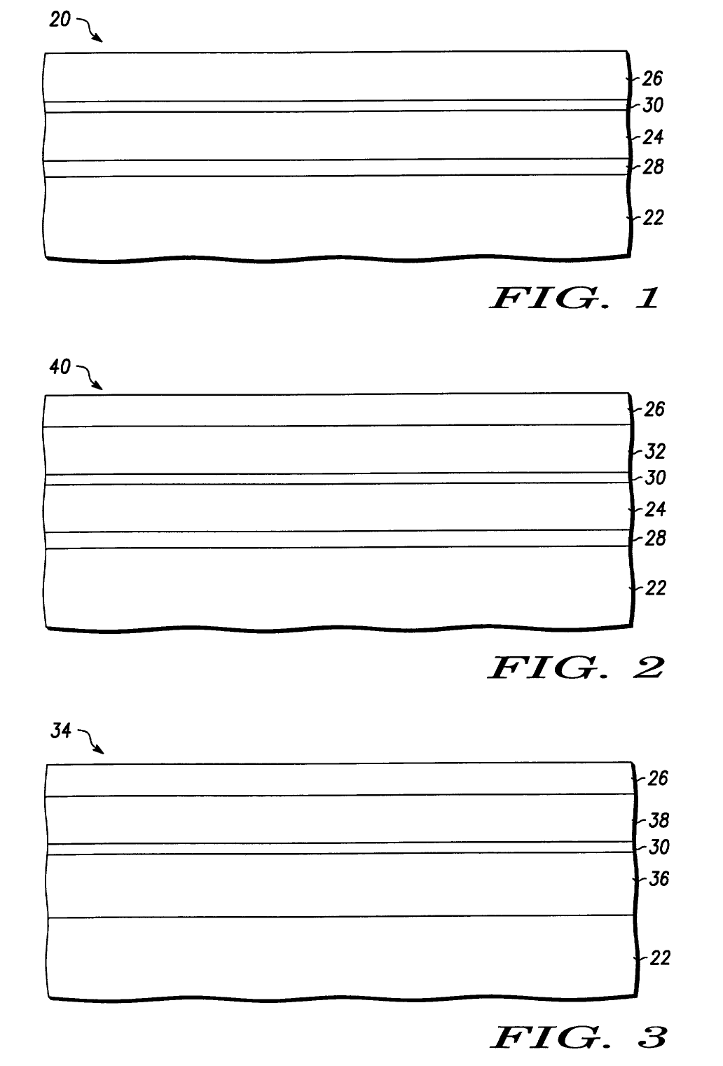

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of SrzBa1-zTiO3, where z ranges from 0 to 1 and the amorphous intermediate layer is a layer of silicon oxide (SiOx) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily, however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (mm) and preferably a thickness of about 0.5 mm to 10 mm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—C. By way of a preferred example, 1-2 monolayers of Ti—As or Sr—Ga—C have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably have a thickness of at least 5 nm to ensure adequate crystalline and surface quality and is formed of a monocrystalline SrZrO3, BaZrO3, SrHfO3, BaSnO3 or BaHfO3. For example, a monocrystalline oxide layer of BaZrO3 can grow at a temperature of about 700° C. The lattice structure of the resulting crystalline oxide exhibits a 45° rotation with respect to the substrate silicon lattice structure.

An accommodating buffer layer formed of these zirconate or hafnate materials are suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 mm. A suitable template for this structure is 1-10 monolayers of zirconium-arsenic (ZrAs), zirconium-phosphorus (Zr—P), hafnium-arsenic (HfAs), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45° rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising an II-VI material overlying a silicon substrate. The substrate is preferably a silicon wafer as described above. A suitable accommodating buffer layer material is SrxBa1-xTiO3, where x ranges from 0 to 1, having a thickness of about

2-100 nm and preferably a thickness of about 5-15 nm. Where the monocrystalline layer comprises a compound semiconductor material, the 11-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc

followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in Example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsxP1-x superlattice, wherein the value of x ranges from 0 to 1. In accordance with another aspect, buffer layer 32 includes an InyGa1-yP superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material, which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably have a thickness of about 100-200 nm. The template for this structure can be the same as that described in Example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer, which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in Example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with Example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOx and SrzBa1-zTiO3 (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In a similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context, the terms “substantially equal” and “substantially matched” mean that there is sufficient similarity between the lattice constants to permit the growth of a high quality crystalline layer on the underlying layer.

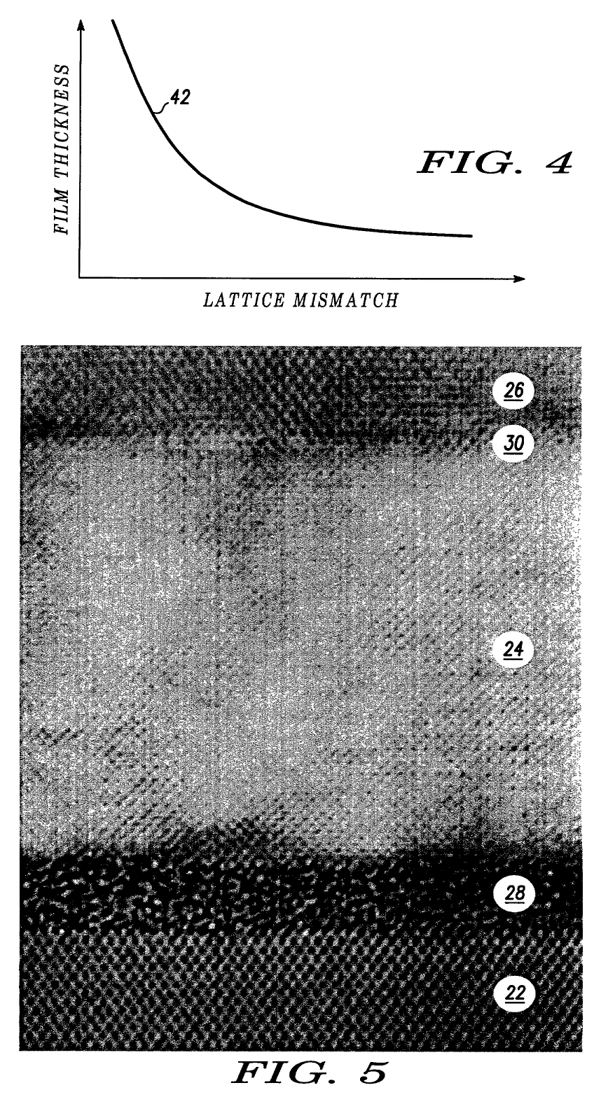

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrxBa1-xTiO3, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As bond, any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO3 accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

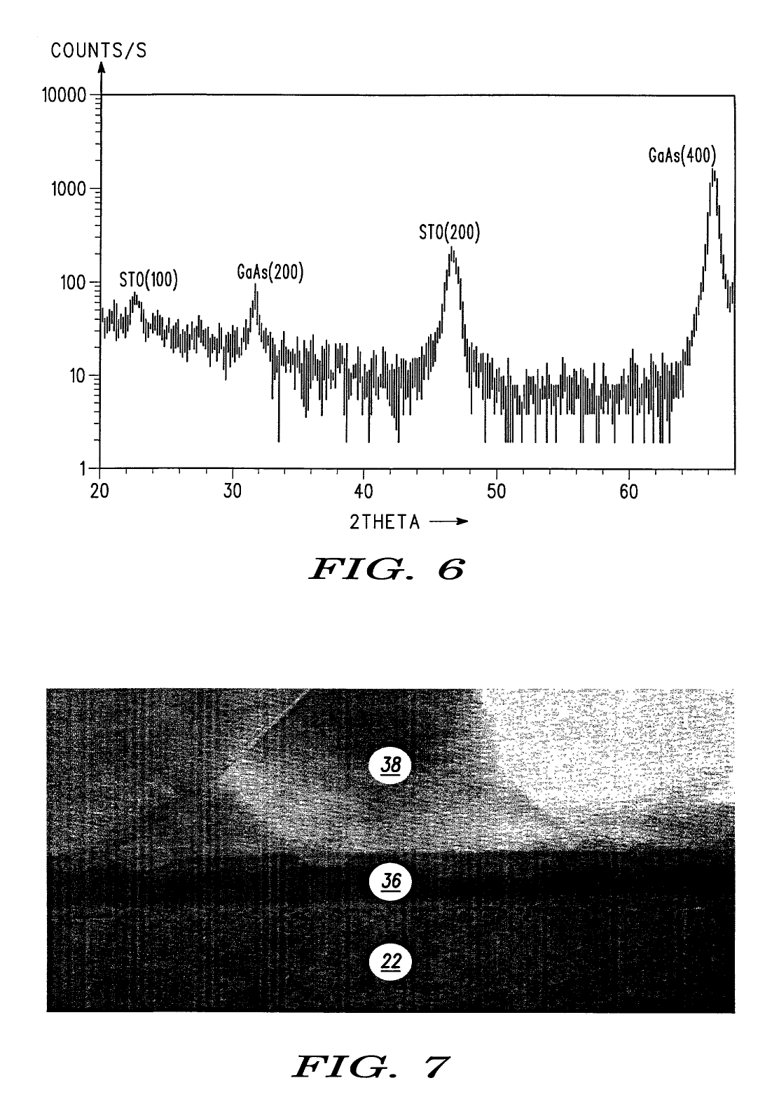

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) oriented.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If, instead, the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described, in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO3 accommodating buffer layer was grown epitaxially on silicon substrate 22. During this growth process, an amorphous interfacial layer form as described above. Next, additional monocrystalline layer 38 comprising a compound semiconductor layer of GaAs is formed above the accommodating buffer layer and the accommodating buffer layer is exposed to an anneal process to form amorphous oxide layer 36.

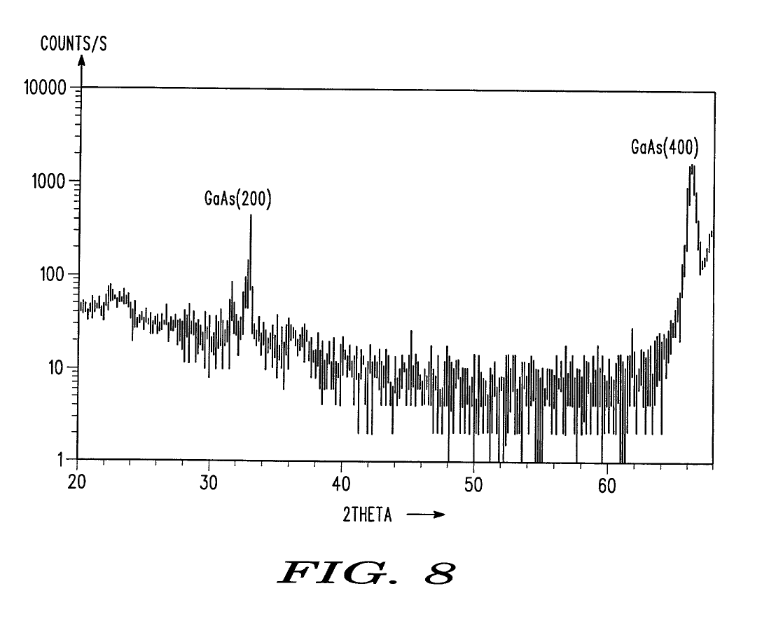

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) oriented, and the lack of peaks around 40 to 50 ° indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS.

9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of SrzBa1-zTiO3 where z ranges from 0 to 1. However, layer 54 may also comprise any of those compounds previously described with reference to layer 24 in FIGS. 1-2 and any of those compounds previously described with reference to layer 36 in FIG. 3 which is formed from layers 24 and 28 referenced in FIGS. 1 and 2.

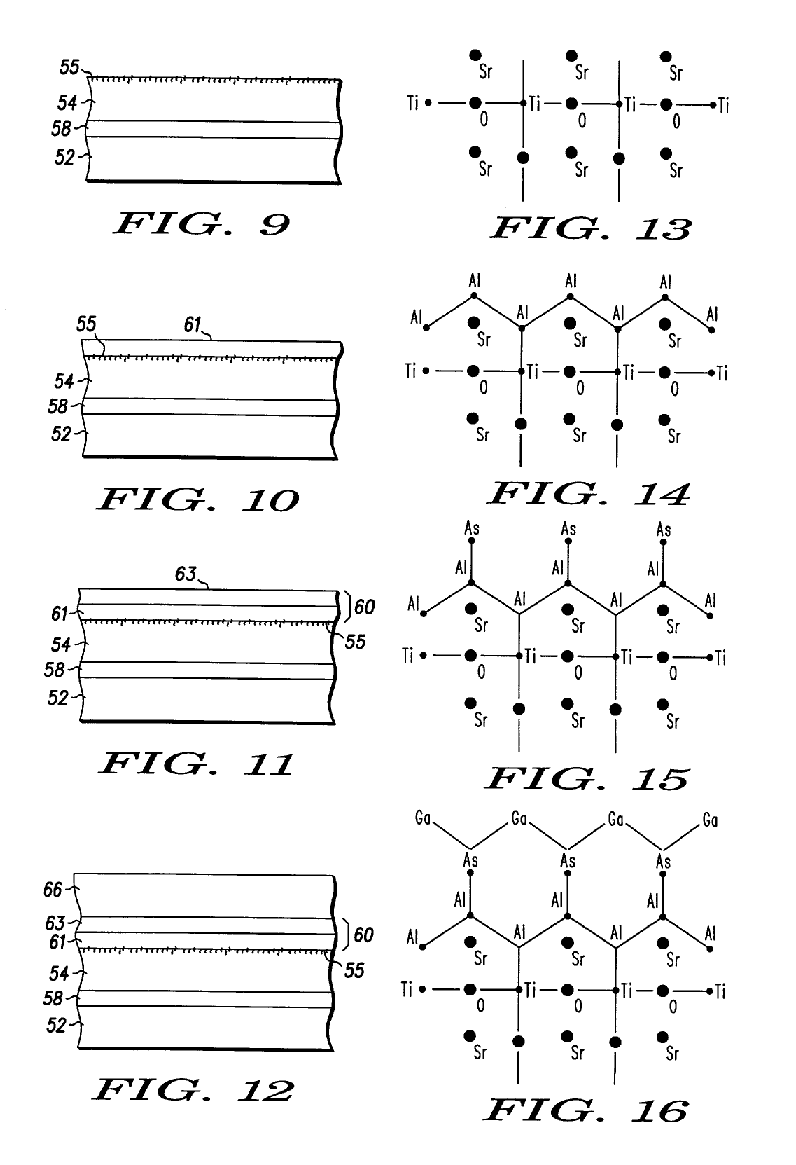

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as

elements, which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS.

13-16 illustrate the growth of GaAs (layer 66) on the strontium-terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δGaAs)

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium-terminated surface of a strontium titanate monocrystalline oxide layer. An aluminum surfactant layer is deposited on top of the strontium-terminated surface and bonds with that surface as illustrated in FIG. 14, which reacts to form a capping layer comprising a monolayer of Al2Sr having the molecular bond structure illustrated in FIG. 14 which forms a diamond-like structure with a sp3 hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16, which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant-containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate, which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from Groups III, IV and V of the periodic table and is defect-free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer, which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing Group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

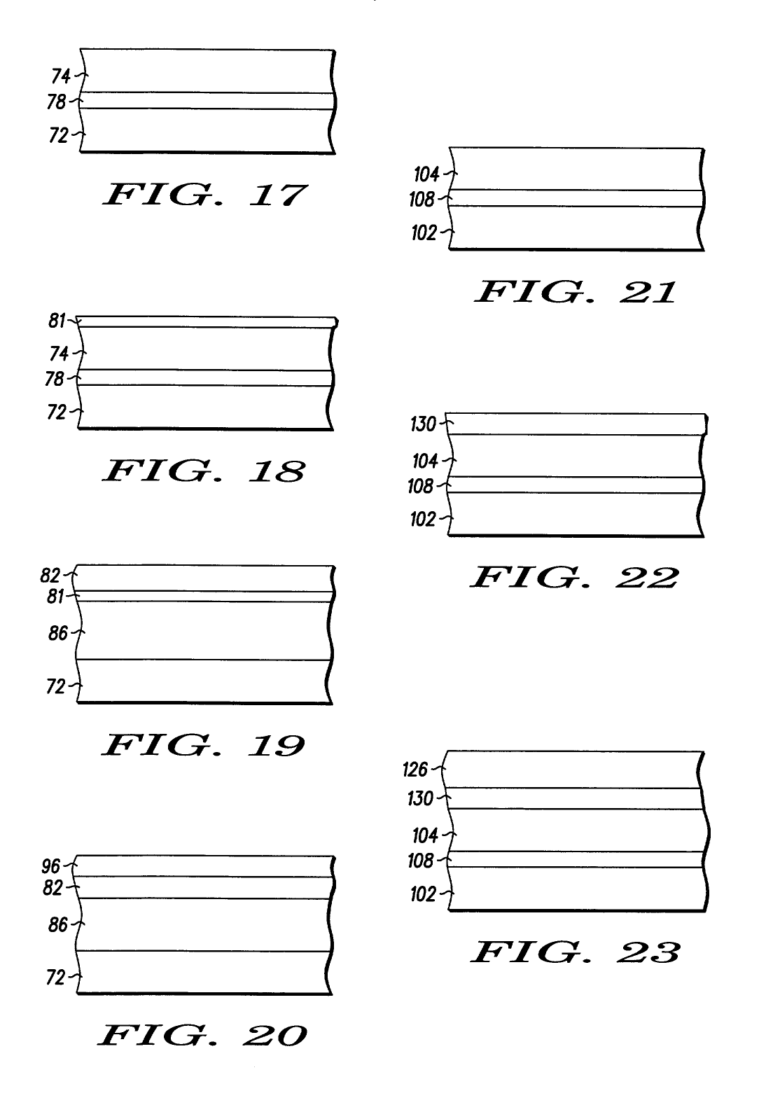

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two-dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

The template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity, which absorbs stress, build up between layers having lattice mismatch. Materials for template 130 may include, but are not limited to, materials containing Si, Ga, In, and Sb such as, for example, AlSr2, (MgCaYb)Ga2, (Ca,Sr,Eu,Yb)In2, BaGe2As, and SrSn2As2.

A monocrystalline material layer 126 is epitaxially grown over template layer 130 to achieve the final structure illustrated in FIG. 23. As a specific example, a SrAl2 layer may be used as template layer 130 and an appropriate monocrystalline material layer 126 such as a compound semiconductor material GaAs is grown over the SrAl2. The Al—Ti (from the accommodating buffer layer of layer of SrzBa1-zTiO3 where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising SrzBa1-zTiO3 to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes a sp3 hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl2 layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There is a multiplicity of other combinations and other embodiments of the present invention. For example, the present invention includes structures and methods for fabricating material layers, which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

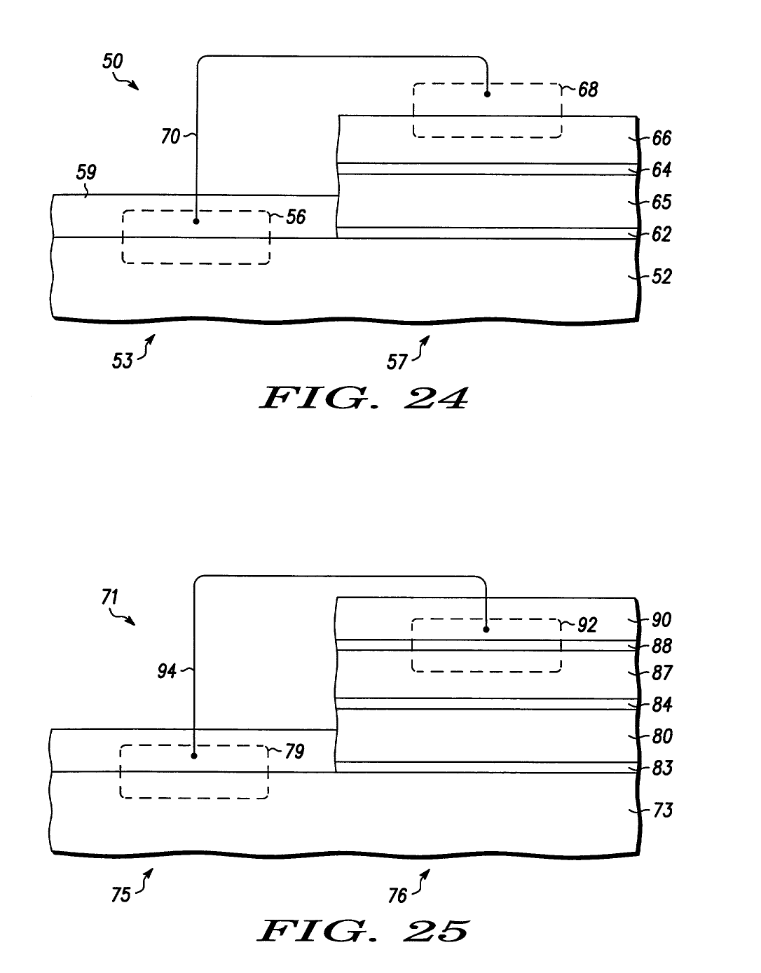

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS-integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and reacts with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form a monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited, overlying second template layer 64 by a process of molecular beam epitaxy. The deposition of layer 66 is initiated by depositing a layer of arsenic onto template 64. This initial step is followed by depositing gallium and

arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component, schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 is formed from a compound semiconductor material. Layers 80 and 83 may be subject to an annealing process as described above in connection with FIG. 3 to form a single amorphous accommodating layer.

A semiconductor component 92 generally indicated by a dashed line is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a Group III-V compound and semiconductor component 92 is a radio frequency amplifier that takes advantage of the high mobility characteristic of Group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

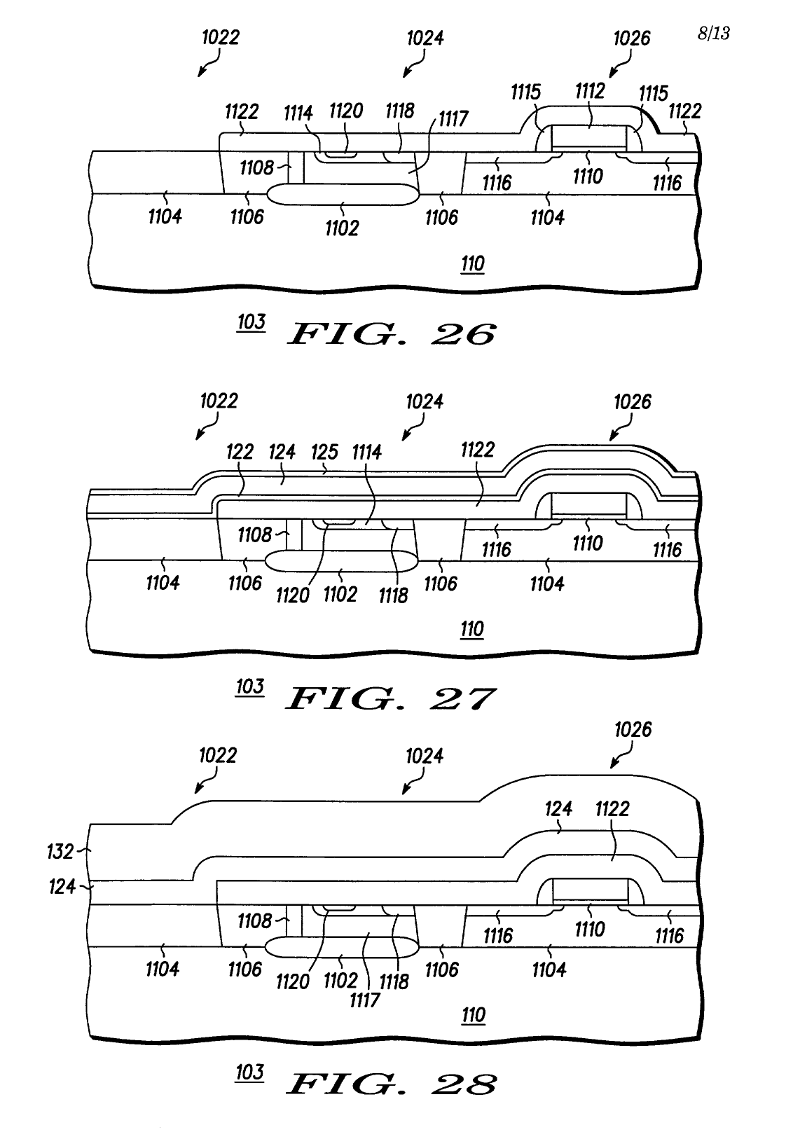

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and a MOS portion 1026. Within bipolar portion 1024, the monocrystalline silicon substrate 110 is doped to form an N+ buried region 1102. A lightly p-type doped epitaxial monocrystalline silicon layer 1104 is then formed over the buried region 1102 and the substrate 110. A doping step is then performed to create a lightly n-type doped drift region 1117 above the N+ buried region 1102. The doping step converts the dopant type of the lightly p-type epitaxial layer within a section of the bipolar region 1024 to a lightly

n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N+ doped regions 1116 and the emitter region 1120. N+ doped regions 1116 are formed within layer 1104 along adjacent sides of the gate electrode 1112 and are source, drain, or source/drain regions for the MOS transistor. The N+ doped regions 1116 and emitter region 1120 have a doping concentration of at least 1E19 atoms per cubic centimeter to allow ohmic contacts to be formed. A p-type doped region is formed to create the inactive or extrinsic base region 1118, which is a P+, doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point is the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a

N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

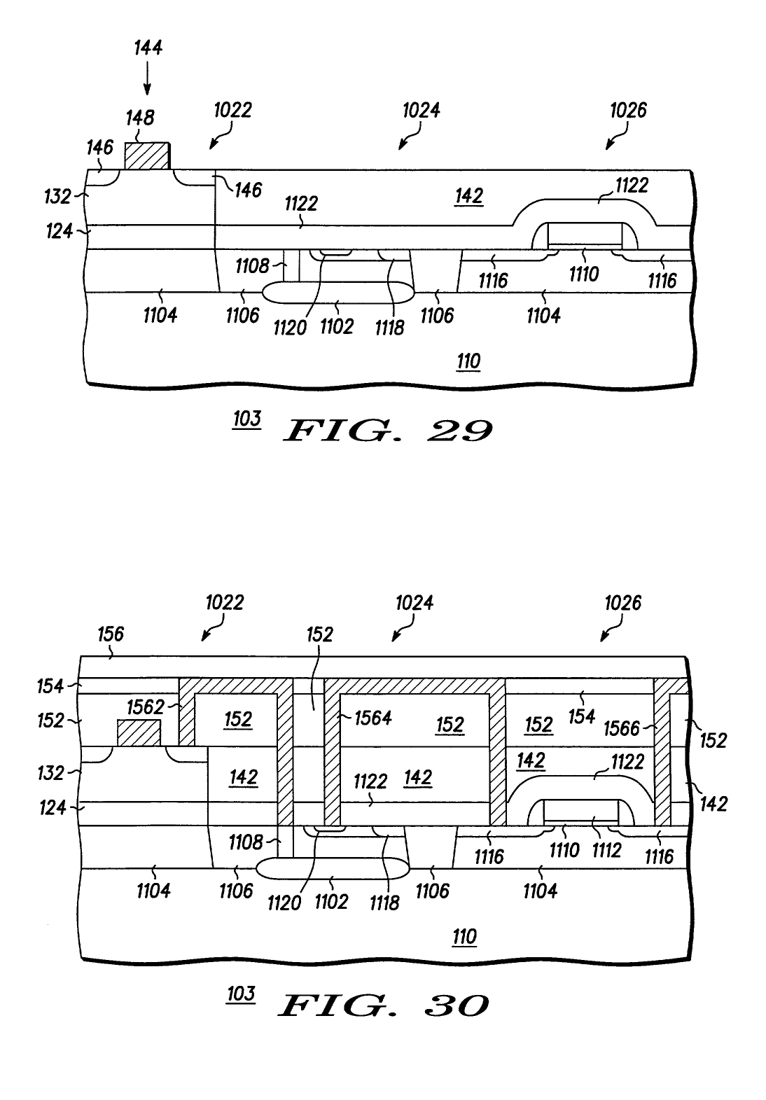

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 15 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

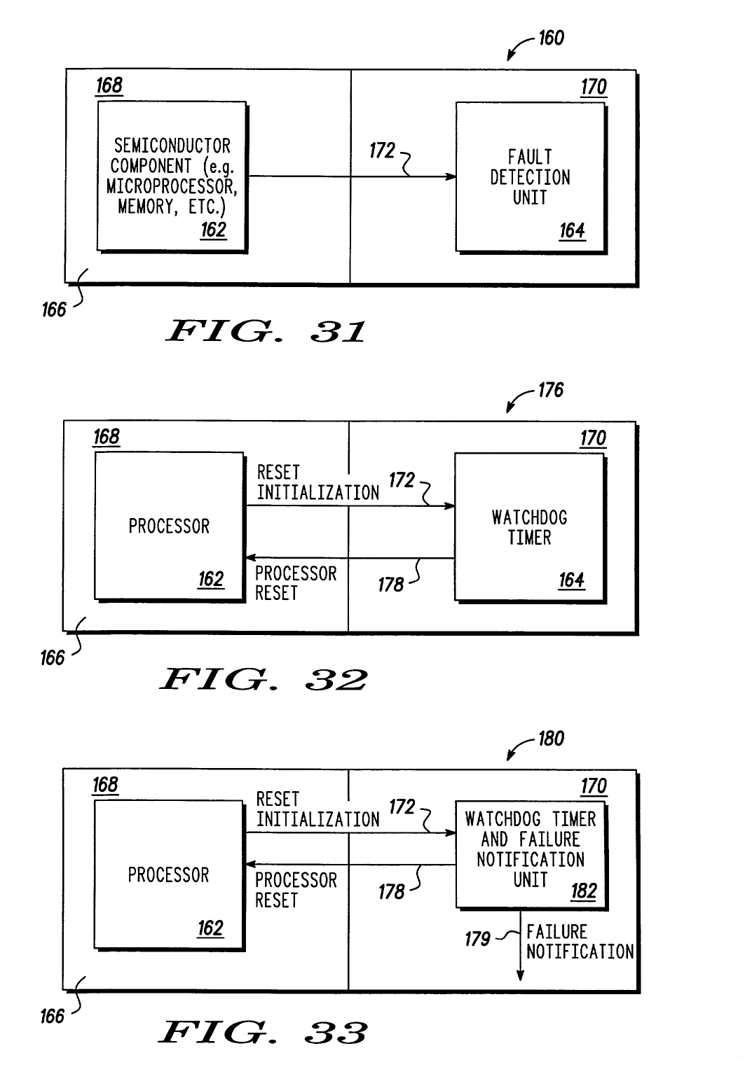

A monocrystalline compound semiconductor layer 132 is then epitaxially grown overlying the monocrystalline portion of accommodating buffer layer 124 as shown in FIG. 28. The portion of layer 132 that is grown over portions of layer 124 that is not monocrystalline may be polycrystalline or amorphous. The compound semiconductor layer can be formed by a number of methods and typically include a material such as gallium arsenide, aluminum gallium arsenide, indium phosphide, or other compound semiconductor materials as previously mentioned. The thickness of the layer is in a range of approximately 15,000 nm, and more preferably 100-2000 nm. Furthermore, additional monocrystalline layers may be formed above layer 132, as discussed in more detail below in connection with FIGS. 31-32.

In this particular embodiment, each of the elements within the template layer is also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph

is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N+) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions, 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

1. Fault Tolerant Systems

The term “fault tolerant system” is used herein to refer to systems that have fault remediation properties so as to be able to continue operation correctly, even in the presence of faults in its components. A fault is the erroneous state of hardware or software due to failure in its components. A failure is the inability of hardware or software to deliver service that meets its specifications. An error is the manifestation of a fault. Errors, and the faults that cause them, can be transient, intermittent or permanent. A transient failure is one that is caused by temporary and unpredictable change in the hardware such as due to an alpha particle toggling a bit in memory. An intermittent fault is one that manifests occasionally due to unstable conditions of hardware or software. A permanent or hard fault is a continuous and stable error state.

Faults are classified as crash faults, fail-stop faults, incorrect computation faults and Byzantine faults. The present invention may also be applied to other fault classes. Under the crash fault model, the faulty component does not respond to any internal or external stimuli. A fail-stop fault is similar to a crash fault except that the faulty component indicates to the rest of the system that it is faulty before entering the state where it does not respond to any stimuli. In an incorrect computation fault, the faulty component will continue to respond but the value of the result may be incorrect. Under a Byzantine fault mode, a faulty component may behave in such a manner that another fault-free component in the system may be identified as faulty. It is believed that the various classes and types of faults outlined above are well understood in light of research that has been conducted in the field of fault-tolerance.

So called “rad hard” systems are designed to be able to withstand the detrimental effects of radiations. It is well known that compound semiconductor materials such as GaAs are better suited for the development of “rad hard” systems, (i.e., radiation hardened systems) than standard CMOS devices. It is also well known that semiconductor circuits designed in compound semiconductor materials can operate at much greater speeds than those designed in standard CMOS, but power consumption is an issue in such systems.

Two aspects of fault remediation and fault-tolerant system design according to the principles of the present invention will now be discussed. In a first aspect, fault detection (also called fault diagnosis) is provided and in a second aspect, fault recovery is carried out. In many cases, these two aspects may not be considered as separate but are unified to develop a robust fault-tolerant system. The present invention, in one aspect, relies upon the “rad-hard” properties and high-speed circuit capabilities of new compound semiconductor structures described above to address the fault-tolerant system design issues in both, fault diagnosis and fault recovery areas.

Fault Remediation of the Fault Diagnostic Type

Referring now to FIGS. 31-38, one of the harmful effects of radiation is that it can lead to transient faults or even permanent damage in semiconductor systems. Different types of semiconductor systems are affected differently. For example, semiconductor systems that are built using silicon technologies such as CMOS are impacted to a much greater degree than those built using compound semiconductors. However, since many semiconductor structures such as complex logic circuits, microprocessors, memories, etc. can be produced more efficiently and consume much less power when implemented in silicon technologies such as CMOS, significant benefits can be gained if successful remediation of radiation effects can be achieved. Examples according to principles of the present invention, set forth herein relate to semiconductor structures of the type described above. These examples reflect fabrication with CMOS logic preferably on the same silicon substrate, or die. In one instance, conventional CMOS semiconductor structures, such as computing and storage devices, are fabricated according to conventional CMOS techniques, while fault remediation systems are fabricated using selected compound semiconductor materials such as GaAs. The present invention also applies to other semiconductor technologies. Whether based in silicon or not such as MOS and NMOS.

Most preferably, compound semiconductor materials described in the above section entitled “Semiconductor Structures” are employed in carrying out the present invention, so as to enable the fault remediation operations to function correctly (even in the presence of harmful radiation) to detect or otherwise remediate faults in CMOS devices which are more prone to these types of faults. FIGS. 31-38 illustrate a semiconductor structure generally indicated at 160, having semiconductor substructures 162, 164 fabricated on a single monocrystalline silicon substrate or die 166. The semiconductor structure 160 is divided into a first CMOS region 168 and a second, compound semiconductor region 170. In FIG. 31, semiconductor substructure 162 represents a generalized CMOS-implemented structure, and can comprise virtually any such structure known today. Semiconductor substructure 164 is constructed according to the principles set forth above, being presented with a monocrystalline material layer comprising semiconductor material, compound semiconductor material, and/or other types of materials such as metals and non-metals, formed by utilizing a compliant substrate.

In FIG. 31, semiconductor substructure 164 comprises a fault detection unit, and can be constructed according to any of such known devices. For example, if the CMOS substructure 162 comprises a computation engine, it performs some computations and sends the results to the fault detection unit 164 to check for validity. Upon detection of a fault, substructure 164 can provide any of the number of conventional responses, such as providing an annunciating function to an operator, or sending a recommendation that further operation of substructure 162 be suspended until the fault occurrence is externally rectified. As indicated in FIG. 31, a communication path 172 from substructure 162 to substructure 164 is provided for this purpose.

Referring now to FIGS. 32-37, and initially to FIG. 32, various examples are given with reference to a number of different fault models. Even though many of these examples are shown using a processing element such as a microprocessor, the present invention is applicable to virtually any semiconductor. It should be noted at the outset, that each of the semiconductor structures illustrated in FIGS. 32-37, include CMOS-implemented substructure 162 and semiconductor substructure 164, constructed according to the principles and features described above with reference to FIGS. 1-30.

Referring now to FIG. 32, semiconductor substructure 162 represents a conventional processor implemented in CMOS and semiconductor substructure 164 represents a conventional watchdog timer device. FIG. 32 illustrates a crash fault model, where the component either works correctly, or, under the presence of a fault, stops responding to any stimuli. For example, such a situation can be encountered if some data output on line 172 becomes corrupted in memory due to radiation and this causes the processor 162 to assume an unknown state or even an infinite software loop. Crash faults are typically detected through the use of a watchdog timer. As long as the processor is alive, the processor 162 resets the watchdog timer 164 at some fixed interval, via line 178. However, if the processor 162 crashes, the timer 164 can be implemented to issue a failure notification in a conventional manner.

Based upon the system requirements and designs, a watchdog timer device might perform one of many possible actions such as resetting the processor, shutting down the subunit, etc. FIG. 33, for example, shows a semiconductor structure 180 which includes a microprocessor 162 implemented in CMOS and interfacing with a watchdog timer 182 implemented in semiconductor material of the type described above with reference to FIGS. 1-30. The arrangement of FIG. 33 illustrates a fail-stop fault model, where the CMOS component 162 encounters a crash fault but before it fails, an indication of the failure is provided to the rest of the system via line 179. A method of constructing such systems is to add the notification capability to the fault detection mechanism in systems that encounter crash faults. The watchdog timer 182 in FIG. 33 differs from the watchdog timer 164 in FIG. 32, in that it has additional logic to notify the rest of the system about the failure of the processor, via line 179. The rest of the functional system now can decide the course of action in response to the fault such as resetting the processor via line 178, for example.

In an incorrect computation fault model, the fault component continues to operate and deliver results but the values of the results are incorrect. As an example, with reference to FIG. 34, a semiconductor structure 186 includes a semiconductor substructure 162 comprising a processor with a memory array and optional units such as an adder circuit or just a memory array, implemented in CMOS. In FIG. 34, semiconductor structure 186 further includes substructure 164 comprising a “CRC generation and CRC check device” implemented in a monocrystalline semiconductor structure formed by utilizing a compliant substrate, as described above with reference to FIGS. 1-30. When exposed to radiation, a state change in substructure 162 causes the memory to deliver a wrong value.

There are a number of approaches to fault remediation and especially to designing fault-tolerant systems to deal with incorrect computation faults. One approach is detecting the presence of faults and then isolating the component such that it appears to have a crash or fail-stop fault and then let the system take appropriate actions. The faults are detected using redundancies and acceptance criteria. In an affected memory component, the CRC of the data are computed and stored with the data. When the data is retrieved, the CRC is recomputed and compared with the stored CRC. If there is a mismatch, the occurrence and perhaps nature of the error is noted. With reference to FIG. 34, the CRC generation and checking device is implemented in substructure 164, while the storage is implemented in CMOS to take advantage of greater densities and lower power consumption.

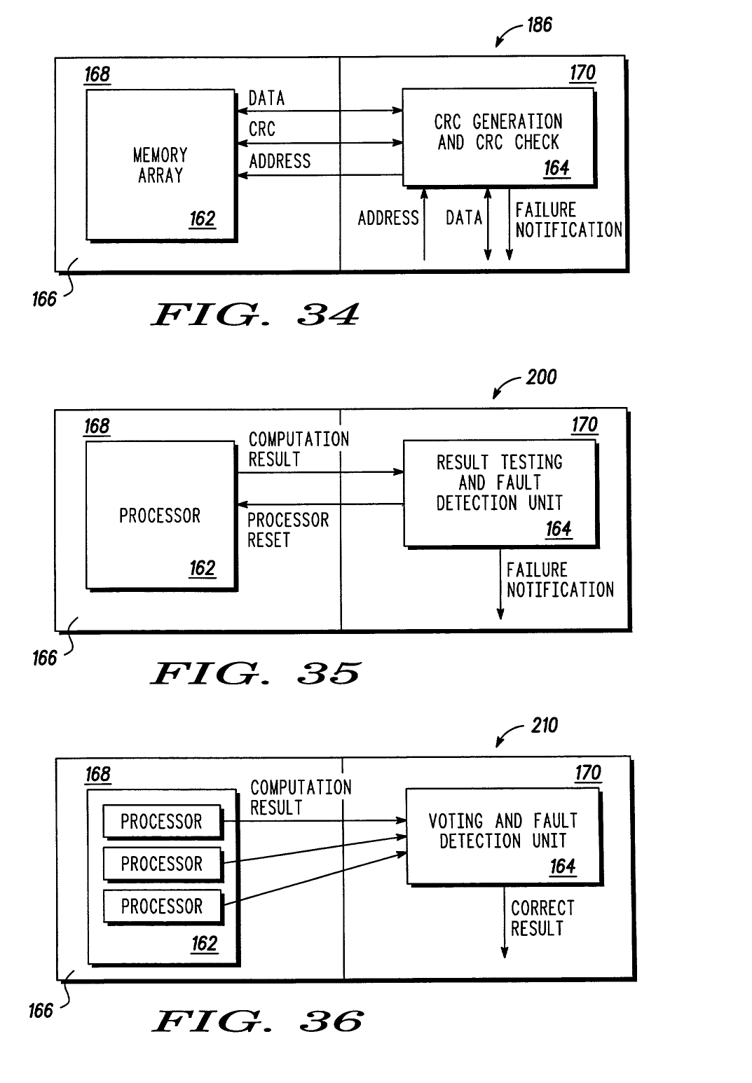

With reference to FIG. 35, a semiconductor structure 200 with computation elements is shown. The semiconductor structure 200 includes a conventional processor or computational element 162 formed in CMOS. Processor 162 is coupled for communication with a “result testing and fault detection unit” remediation device 164, implemented in a preferred monocrystalline semiconductor structure formed by utilizing a compliant substrate, as described above with reference to examples and descriptions given with reference to FIGS. 1-30. When exposed to radiation, a state change in substructure 162 causes the program running on the processor to deliver a wrong value. The state change may occur, for example, in a section of a hardware unit associated with processor 162, such as an adder or memory component.

Results from processor 162 are transmitted to fault remediation device 164. The result is tested in device 164 against acceptance criteria and if the result does not agree, then than the presence of a fault is inferred. The selection of the acceptance criteria is based upon the computation that is performed and the requirements of the systems involved. Examples of such requirements include testing for bounds for array indices, testing to see if the result lies within expected ranges, etc.

With reference to FIG. 36, a semiconductor structure 210 includes a semiconductor substructure 162 comprising a processor array embodied in CMOS and a “voting and fault detection unit” 164 implemented in a monocrystalline semiconductor substructure formed according to description and examples of FIGS. 1-30, by utilizing a compliant substrate. “Fault masking” is widely used in practice to deal with incorrect computation. In this technique, the computation is replicated and a voter compares the results of various replicated units and selects the majority result. The replication is preferably made in a space domain, with multiple units working simultaneously on the computations. However, replication in time or a combination of replication in time and space may also be employed. It is also well known to those skilled in the art that to detect N faulty components, one must have at least 2N+1 replicas. The voting and result testing circuit is embodied in compound semiconductor region to operate with the processing unit in the CMOS region.

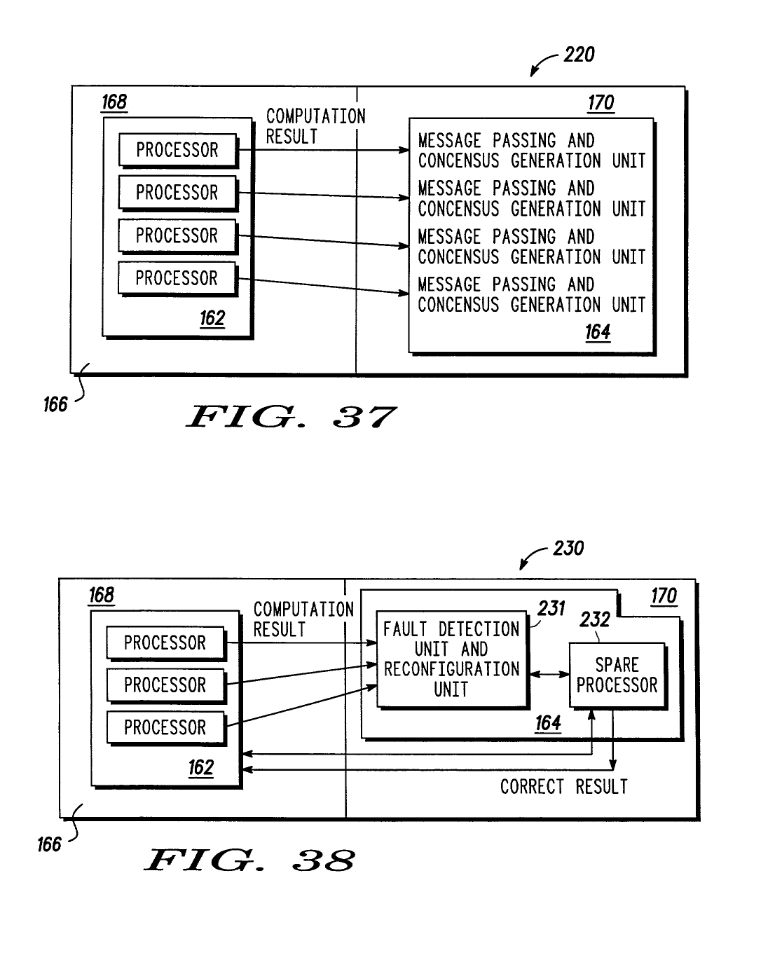

Under a Byzantine fault model, a faulty component behaves maliciously and this may lead to a non-faulty component to be declared as faulty. With reference to FIG. 37, a semiconductor structure 220 includes a semiconductor substructure 162 comprising a processor array implemented in CMOS and a semiconductor substructure 164 comprising an array of “message passing and consensus generation units”. Byzantine faults are detected, with the substructures 162, 164 passing messages to each other and reaching a consensus in a known manner as to the correct result. It is well known to those skilled in the art that a system must implement 3N+1 components to deal with N faulty components. Remediation for Byzantine faults implements the message passing and testing units in the monocrystalline semiconductor material formed by utilizing a compliant substrate, in the manner set forth above with reference to FIGS. 1-30.

Fault Remediation of the Fault Recovery Type

Fault diagnostic techniques were described above. In a practical system in which continued reliable operation is imperative, the system usually takes corrective “fault recovery” actions to deal with the faults detected. A number of fault recovery schemes are known to those familiar with the field of fault-tolerant computing, and are contemplated in carrying out the present invention. Such schemes typically rely upon the appropriate use of time and space redundancy. Many of the techniques deploy one or more spare processors that take the place of a faulty processor. A major problem with such systems is that a fault recovery type of fault remediation is a time-consuming process. There are a number of critical real-time systems that require the delivery of a functionally correct result at or before the deadline, even in the presence of faults.

The arrangement shown in FIG. 38 includes a semiconductor structure 230 having a substructure 162 comprising an array of processors implemented in CMOS. Semiconductor circuit 230 further includes a “fault detection unit and reconfiguration unit” 231 implemented in semiconductor substructure 164. In the arrangement shown in FIG. 38, a spare processor 232 is included as part of the substructure 164 according to the principles and examples set forth above with respect to FIGS. 1-30, formed by utilizing a compliant substrate. According to one aspect of the present invention, implementation of semiconductor substructure 164 can be expected to operate faster than an equivalent substructure implemented in a conventional technology, such as CMOS. During the course of developing practical implementations of semiconductor substructures according to FIGS. 1-30, power consumption has been found to be an important factor. To mitigate power consumption, computations in substructure 164 are preferably performed by processors 162 implemented in CMOS. Fault-detection logic systems, such as those described above, or otherwise conventionally known are used to diagnose faulty components. Since the computations are regularly performed on CMOS processors, the system can be designed to operate with acceptable power consumption. Whenever a fault is detected, the spare processor is powered up and the tasks that were being executed on the faulty processors are executed on the spare processor 232. Since the spare processor can be expected to operate at much higher speeds than an equivalent CMOS processor and substructure 162, the system implemented in a semiconductor structure 230 can be designed such that task deadlines are met. Alternatively, one may produce a result with less accuracy through techniques such as table look ups etc., but fast enough to meet the critical deadline. The surge in power consumption can be tolerated since transient faults can be expected to be relatively rare.

Fault remediation systems according to principles of the present invention can be employed in conjunction with their related data systems, exclusively on one of the new types of compound semiconductor structures described above. Alternatively, fault remediation systems according to the present invention can share a common substrate with conventionally-constructed data systems. Examples of such integrated semiconductor structure packages have been described above with reference to FIGS. 31-38. Frequently, common semiconductor materials such as silicon or conventional compound semiconductor materials, such as conventional GaAs, are chosen for reasons of economy of fabrication and experience in practical working implementations. However, the operating characteristics of semiconductor structures embodied in many conventional materials are known to degrade when subjected to the influence of radiation, such as gamma and neutron radiation. Although deteriorated by incoming radiation, it is known that semiconductor devices based on conventional materials are capable of maintaining a measure of data-related capability, although data integrity suffers at times from random or intermittent faults. In order to prevent an unacceptable level of impairment which would render the device practically useless, the present invention provides an elevated radiation resistance, i.e., tolerance, whether or not aspects of the present invention are used in combination with conventional radiation hardening techniques.

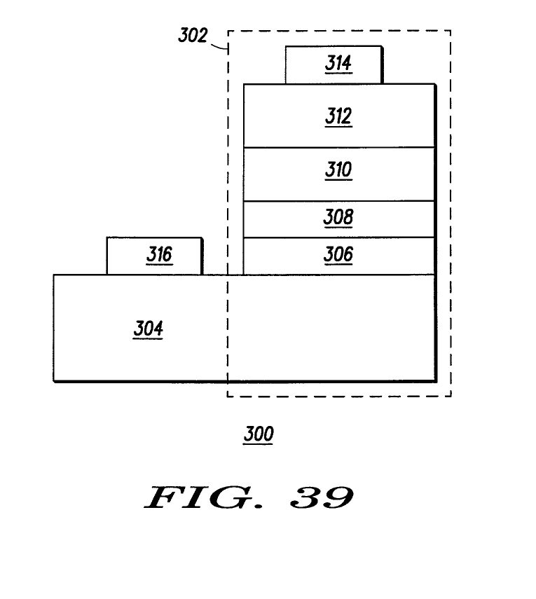

Turning now to FIG. 39, a semiconductor structure according to principles of the present invention is generally indicated at 300. Reference numeral 302 indicates a physical realization of an exemplar fault remediation semiconductor substructure referred to in FIGS. 31-38, above. Semiconductor structure 316 indicates a physical realization of a conventional substructure, such as the substructure 162 described above. Both substructures 302, 316 are built upon a common substrate 304, preferably a monocrystalline substrate 304 of the type described above with reference to FIGS. 1-30.

Also included in semiconductor substructure 302 is a monocrystalline material layer 312 comprised of semiconductor material, compound semiconductor material, and/or other types of materials such as metals and nonmetals formed by utilizing a compliant substrate 308. An amorphous oxide layer 306 is located between the monocrystalline silicon substrate 304 and a monocrystalline perovskite oxide material layer 308. If desired, optional layers 310, such as a gettering region, maybe located between monocrystalline perovskite oxide material layer 308 and the monocrystalline compound semiconductor material layer 312. Structure part 314 is integrated with substructure 302. Structure part 314 represents a physical realization of the semiconductor substructures 164 described above with reference to FIGS. 31-38. Not shown in FIG. 39 are conventional communication paths to allow devices 314, 316 to communicate with one another and with external devices and systems, as well.

In the various examples given above, it was assumed that faults to be remediated arise from the effects of radiation incident on data emitting semiconductor components. It should be understood, however, that the present invention applies equally well to the remediation of faults arising from virtually any cause of whatever nature, and not only those faults arising from exposure to radiation. Further, it should be understood that the present invention pertains to devices of whatever nature that emit data. Examples given above are based on familiar systems having memory storage and computational capabilities. However, the present invention pertains to circuits' devices and systems of whatever nature that involved data. For example, fault remediation according the principles of the present invention can be associated with devices that merely receive a data from wireless or land-based communication networks. As such, it is possible that the faults remediated according to principles of the present invention do not arise in the data-receiving device, but which are nonetheless potentially present in the output of the data-receiving device.

Further, examples of fault remediation according to principles of the present invention have been given above with respect to monolithic semiconductor structures, that is, structures which include not only fault remediation substructures, but also data-emitting substructures. It should be understood that the present invention also pertains equally well to stand-alone fault remediation structures, most preferably semiconductor structures formed by utilizing a compliant substrate, as described above with reference to examples and descriptions given with reference to FIGS. 1-30. In such instances, it is contemplated that fault remediation according to principles of the present invention responds to data emitted from external, nearby or remote, circuits devices and systems known today. For example, a semiconductor structure with fault remediation functions, constructed according to principles of the present invention can be coupled to receive data from an external communication line, an external and remotely located data sending unit, an external and nearby located data-emitting integrated circuit, mechanical or electromechanical apparatus.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
the first semiconductor substructure having an output port for outputting data, and including a first portion of said monocrystalline silicon substrate;
a second semiconductor substructure including a second portion of said monocrystalline silicon substrate;
said second semiconductor substructure further including an amorphous oxide material overlying the monocrystalline silicon substrate, a monocrystalline perovskite oxide material overlying the amorphous oxide material, a monocrystalline compound semiconductor material overlying the monocrystalline perovskite oxide material, and a semiconductor fault remediation device in said monocrystalline compound semiconductor material having an input port for inputting data; and
a conductive interconnection connecting the output port of said first semiconductor substructure to the input port of said fault remediation device.

2. The semiconductor structure of claim 1 wherein said fault remediation device includes a fault detector which detects faults in data outputted from said first semiconductor substructure.

3. The semiconductor structure of claim 1 wherein said fault remediation device includes a fault corrector which corrects faults in data outputted from said first semiconductor substructure.

4. The semiconductor structure of claim 1 wherein the monocrystalline silicon substrate is oriented in the (100) direction.

5. The semiconductor structure of claim 1 further comprising a template layer formed between the monocrystalline perovskite oxide material and the monocrystalline compound semiconductor material.

6. The semiconductor structure of claim 1 further comprising a buffer material of monocrystalline semiconductor material formed between the monocrystalline perovskite oxide material and the monocrystalline compound semiconductor material.

7. The semiconductor structure of claim 6 further comprising a template layer formed between the monocrystalline perovskite oxide material and the buffer material.

8. The semiconductor structure of claim 6 wherein the buffer material is selected from the group consisting of: Germanium, a GaAsxP1-x superlattice where x ranges from 0 to 1, InyGa1-yP superlattice where y ranges from 0 to 1, and an InGaAs superlattice.

9. The semiconductor structure of claim 1 wherein the monocrystalline perovskite oxide material is selected from the group consisting of: alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin based perovskites, lanthanum aluminate, and lanthanum scandium oxide.

10. The semiconductor structure of claim 1 wherein the monocrystalline perovskite oxide material comprises SrzBa1-zTiO3, wherein z ranges from 0 to 1.

11. The semiconductor structure of claim 1 wherein the monocrystalline compound semiconductor material is selected from the group consisting of: III-V compounds, mixed III-V compounds, II-VI compounds, and mixed II-VI compounds.

12. The semiconductor structure of claim 1 wherein the monocrystalline compound semiconductor material is selected from the group consisting of: GaAs, AlGaAs, InP, InGaAs, InGaP, ZnSe, AllnAs, CdS, CdHgTe, and ZnSeS.

13. A semiconductor structure comprising:
a monocrystalline substrate characterized by a first lattice constant;
the first semiconductor substructure having an output port for outputting data, and including a first portion of said monocrystalline substrate;
a second semiconductor substructure including a second portion of said monocrystalline substrate;
said second semiconductor substructure further including a monocrystalline insulator layer having a second lattice constant different than the first lattice constant overlying the monocrystalline substrate, an amorphous oxide layer between the monocrystalline substrate and the monocrystalline insulator layer, a monocrystalline compound semiconductor layer having a third lattice constant different than the first lattice constant overlying the monocrystalline insulator layer, and a semiconductor fault remediation device in said monocrystalline compound semiconductor material having an input port for inputting data;
the second lattice constant selected to be either equal to the third lattice constant or intermediate the first and third lattice constant; and
a conductive interconnection connecting the output port of said first semiconductor substructure to the input port of said fault remediation device.

14. The semiconductor structure of claim 1 wherein said fault remediation device includes a fault detector which detects faults in data outputted from said first semiconductor substructure.

15. The semiconductor structure of claim 1 wherein said fault remediation device includes a fault corrector which corrects faults in data outputted from said first semiconductor substructure.

16. The semiconductor structure of claim 13 wherein the monocrystalline substrate is oriented in the (100) direction.

17. The semiconductor structure of claim 13 wherein the amorphous oxide layer has a thickness sufficient to relieve strain in the monocrystalline insulator layer.

18. The semiconductor structure of claim 13 further comprising a template layer between the monocrystalline insulator layer and the monocrystalline compound semiconductor layer.

19. The semiconductor structure of claim 13 further comprising a buffer layer between the monocrystalline insulator layer and the monocrystalline compound semiconductor layer.

20. The semiconductor structure of claim 13 wherein the monocrystalline substrate is characterized by a first crystalline orientation and the monocrystalline insulator layer is characterized by a second crystalline orientation and wherein the second crystalline orientation is rotated with respect to the first crystalline orientation.

21. The semiconductor structure of claim 13 wherein the monocrystalline substrate comprises silicon.

22. The semiconductor structure of claim 13 wherein the monocrystalline substrate comprises a material comprising silicon, the monocrystalline insulator comprises an alkaline earth metal titanate and the monocrystalline compound semiconductor material comprises a material selected from the group consisting of: GaAs, AlGaAs, ZnSe, and ZnSeS.

23. The semiconductor structure of claim 22 wherein the monocrystalline insulator layer comprises SrzBa1-zTiO3 where z ranges from 0 to 1.

24. The semiconductor structure of claim 13 wherein the monocrystalline insulator layer comprises an oxide selected from the group consisting of alkaline earth metal zirconates, and alkaline earth metal hafnates and the monocrystalline compound semiconductor layer comprises a material selected from the group consisting of: InP and InGaP.

25. A process for fabricating a semiconductor structure comprising:
providing a monocrystalline silicon substrate having a first lattice constant;
providing a first semiconductor substructure having an output port for outputting data, and including a first portion of said monocrystalline silicon substrate;
providing a second semiconductor substructure which includes a second portion of said monocrystalline silicon substrate;
selecting a material that when properly oriented has a second lattice constant and crystalline structure such that the material can be deposited as a monocrystalline film overlying the second portion of the monocrystalline silicon substrate, the second lattice constant being different than the first lattice constant;
depositing a monocrystalline film of the material overlying the second portion of the monocrystalline silicon substrate, the film having a thickness less than a thickness of the material that would result in strain-induced defects, the monocrystalline film being strained because the first lattice constant is different than the second lattice constant;
forming an amorphous interface layer at an interface between the monocrystalline film and the monocrystalline silicon substrate, the amorphous interface layer having a thickness sufficient to relieve the strain in the monocrystalline film;
selecting a compound semiconductor material having a third lattice constant that is different than the first lattice constant and that when properly oriented can be deposited on the monocrystalline film as a monocrystalline compound semiconductor layer;
epitaxially depositing a monocrystalline layer of the compound semiconductor material overlying the monocrystalline film;
selecting the second lattice constant is to be one of (a) intermediate to the first and third lattice constants and (b) equal to the third lattice constant;
providing a semiconductor fault remediation device in said compound semiconductor material having an input port for inputting data; and
providing a conductive interconnection connecting the output port of said first semiconductor substructure to the input port of said fault remediation device.

26. The process of claim 25 wherein the monocrystalline silicon substrate is orientated in the (100) direction.

27. The process of claim 25, following the formation of the amorphous interface layer, further comprising continuing to deposit the monocrystalline film of the material overlying the monocrystalline silicon substrate.

28. The process of claim 25 further comprising forming a first template layer overlying the monocrystalline silicon substrate to nucleate depositing the monocrystalline film.

29. The process of claim 28 further comprising forming a second template layer overlying the monocrystalline film to nucleate epitaxially depositing the monocrystalline layer.

30. The process of claim 25 wherein the material of the monocrystalline film is selected from the group consisting of: alkaline-earth-metal titanates, alkaline-earth-metal zirconates, and alkaline-earth-metal hafnates.

31. The process of claim 25 wherein the depositing a monocrystalline film comprises epitaxially growing a monocrystalline oxide layer lattice-matched to the monocrystalline silicon substrate.

32. The process of claim 31 wherein the epitaxially growing comprises growing the monocrystalline oxide layer to a thickness of about 2-10 nm.

33. The process of claim 31 wherein the epitaxially growing comprises growing the monocrystalline oxide layer to a thickness of about 5-6 nm.

34. The process of claim 31 wherein the step of growing a monocrystalline oxide layer comprises providing an oxide layer comprising
SrxBa1-xTiO3 where x ranges from 0 to 1.

35. The process of claim 29 wherein the forming a first template layer comprises capping the monocrystalline silicon substrate with 1-10 monolayers of a material selected from titanium, titanium and oxygen, strontium, and strontium and oxygen.

36. The process of claim 35 wherein the compound semiconductor is selected from the group consisting of: GaAs, AlGaAs, GaAsP, and GalnP.

37. The process of claim 35 further comprising depositing a buffer layer overlying the second template layer.

38. The process of claim 37 wherein the depositing a buffer layer comprises epitaxially depositing a superlattice layer of a material selected from the group consisting of: GaAsxP1-x where x ranges from 0 to 1 and lnyGa1-up where y ranges from 0 to 1.

39. The process of claim 38 wherein the compound semiconductor is selected from the group consisting of: GaAs, AlGaAs, GaAsP, GaInAs, InP and GaInP.

40. The process of claim 35 wherein the forming a second template layer comprises capping the monocrystalline film with 1-10 monolayers of a material selected from GeSr and Ge—Ti.

41. The process of claim 40 further comprising epitaxially depositing a buffer layer of germanium on the second template layer.

42. The process of claim 35 wherein the forming a second template layer comprises:
capping the monocrystalline film with 1-10 monolayers of ZnO; and
depositing 1-3 monolayers of zinc rich ZnO overlying the monolayers of ZnO.

43. The process of claim 42 wherein the compound semiconductor is selected from the group consisting of: ZnSe and ZnSeS.

44. The process of claim 35 wherein the forming a second template layer comprises capping the monocrystalline film with 1-2 monolayers of SrS.

45. The process of claim 44 wherein the compound semiconductor layer is ZnSeS.

46. The process of claim 25 wherein the depositing a monocrystalline film comprises providing a monocrystalline oxide layer comprising a material selected from the group consisting of: alkaline-earth-metal zirconates and alkaline-earth-metal hafnates.

47. The process of claim 46 further comprising capping the monocrystalline oxide layer with about 1-10 monolayers of a material M-N or M-O-N wherein M is selected from the group consisting of: Zr, Hf, Sr, and Ba, and N is selected from the group consisting of: As, P, Ga, Al, and In.

48. The process of claim 47 wherein the compound semiconductor is selected from the group consisting of: InP and InGaAs.

49. The process of claim 48 further comprising forming a buffer layer comprising a superlattice comprising InGaAs overlying the 1-10 monolayers.

50. A process for fabricating a semiconductor structure comprising:
providing a monocrystalline silicon substrate;
providing a first semiconductor substructure having an output port for outputting data, and including a first portion of said monocrystalline silicon substrate;
providing a second semiconductor substructure which includes a second portion of said monocrystalline silicon substrate;
depositing a monocrystalline perovskite oxide film overlying the second portion of the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the second portion of the monocrystalline silicon substrate; and
epitaxially forming a monocrystalline compound semiconductor layer overlying the monocrystalline perovskite oxide film;
providing a semiconductor fault remediation device in said compound semiconductor layer having an input port for inputting data; and
providing a conductive interconnection connecting the output port of said first semiconductor substructure to the input port of said fault remediation device.

51. The process of claim 50 wherein the monocrystalline silicon substrate is orientated in the (100) direction.

52. The process of claim 50, following the formation of the amorphous oxide interface layer, further comprising continuing to deposit the monocrystalline perovskite oxide film overlying the monocrystalline silicon substrate.

53. The process of claim 50 further comprising forming a first template layer overlying the monocrystalline silicon substrate to nucleate depositing the monocrystalline perovskite oxide film.

54. The process of claim 53 further comprising forming a second template layer overlying the monocrystalline perovskite oxide film to nucleate epitaxially depositing the monocrystalline compound semiconductor layer.

55. The process of claim 50 wherein the monocrystalline perovskite oxide film is selected from the group consisting of: alkaline-earth-metal titanates, alkaline-earth-metal zirconates, and alkaline-earth-metal hafnates.

56. The process of claim 50 wherein the providing a monocrystalline perovskite oxide film comprises epitaxially growing a monocrystalline perovskite oxide film lattice-matched to the monocrystalline silicon substrate.

57. The process of claim 56 wherein the epitaxially growing comprises growing the monocrystalline perovskite oxide film to a thickness of about 2-10 nm.

58. The process of claim 56 wherein the epitaxially growing comprises growing the monocrystalline perovskite oxide film to a thickness of about 5-6 nm.

59. The process of claim 50 wherein the monocrystalline perovskite oxide film comprises SrxBa1-xTiO3 where x ranges from 0 to 1.

60. The process of claim 54 wherein the forming a first template layer comprises capping the monocrystalline silicon substrate with 1-10 monolayers of a material selected from the group consisting of: titanium, titanium and oxygen, strontium, and strontium and oxygen.

61. The process of claim 60 wherein the monocrystalline compound semiconductor layer is selected from the group consisting of: GaAs, AlGaAs, GaAsP, and GalnP.

62. The process of claim 60 further comprising depositing a buffer layer overlying the second template layer.

63. The process of claim 62 wherein the depositing a buffer layer comprises epitaxially depositing a superlattice layer of a material selected from the group consisting of: GaAsxP1-x where x ranges from 0 to 1 and lnyGa1-up where y ranges from 0 to 1.

64. The process of claim 63 wherein the monocrystalline compound semiconductor layer is selected from the group consisting of: GaAs, AlGaAs, GaAsP, GaInAs, InP and GaInP.

65. The process of claim 60 wherein the forming a second template layer comprises capping the monocrystalline perovskite oxide film with 1-10 monolayers of a material selected from the group consisting of: Ge—Sr and Ge—Ti.

66. The process of claim 65 further comprising epitaxially depositing a buffer layer of germanium overlying the second template layer.

67. The process of claim 60 wherein the forming a second template layer comprises: capping the monocrystalline perovskite oxide film with
1-10 monolayers of ZnO; and depositing 1-3 monolayers of zinc-rich ZnO overlying the monolayers of ZnO.

68. The process of claim 67 wherein the monocrystalline compound semiconductor layer is selected from the group consisting of: ZnSe and ZnSeS.

69. The process of claim 60 wherein the forming a second template layer comprises the step of capping the monocrystalline perovskite oxide film with 1-2 monolayers of SrS.

70. The process of claim 69 wherein the monocrystalline compound semiconductor layer comprises ZnSeS.

71. The process of claim 60 wherein the monocrystalline perovskite oxide film is selected from the group consisting of: alkaline-earth-metal zirconates and alkaline-earth-metal hafnates.

72. The process of claim 71 further comprises capping the monocrystalline perovskite oxide film with about 1-10 monolayers of a material M-N or M-O-N wherein M is selected from the group consisting of: Zr, Hf, Sr, and Ba, and N is selected from the group consisting of: As, P, Ga, Al, and In.

73. The process of claim 72 wherein the monocrystalline compound semiconductor layer is selected from the group consisting of: InP and InGaAs.

74. The process of claim 73 further comprising forming a buffer layer comprising a superlattice comprising InGaAs overlying the 1-10 monolayers.
